(19) United States
(12) Patent Application Publication
(10) Pub. No.: US 2014/0001929 A1
(43) Pub. Date: Jan. 2, 2014

(54) MOBILE INFORMATION AND ENTERTAINMENT UNIT FOR HOSPITAL PATIENTS

(71) Applicant: EUFINA AG, Zug (CH)

(72) Inventor: Frank REMIH, Zug (CH)

(73) Assignee: Eufina AG, Zug (CH)

(21) Appl. No.: 13/674,553

(22) Filed: Nov. 12, 2012

(30) Foreign Application Priority Data
Jun. 28, 2012 (DE) 10 2012 012 882.7

(51) Int. Cl. H05K 5/00

(52) U.S. Cl. CPC H05K 5/0017
USPC 312/7.2

(57) ABSTRACT

The invention relates to a mobile information and entertainment unit (1) with a base body (2), which comprises side walls (3, 4, 5, 6), at least one bottom wall (7) and at least one openable cover (22), which enclose an interior (8), and with a screen (14) for displaying information and entertainment content, wherein the screen (14) is mounted on a swivel arm (13), the swivel arm (13) and the screen (14) when in use are disposed outside the interior (8), the swivel arm (13) and the screen (14) can be stored in a rest position in the interior (8), and when the screen (14) and swivel arm (13) are stored in the interior (8) the cover (22) can be closed.

The present invention relates to a device with the features of the pre-characterising part of claim 1.

Information and entertainment units provide the users with access to internet material and email functions as well as TV and radio functions. These functions are hereinafter generically termed “infotainment”. The units intended for such infotainment functions are hereinafter termed “infotainment systems”. They are normally computer-based with internet access and a screen, which is expediently in the form of a touchscreen. Such infotainment systems are expedient particularly in hospitals, where on the one hand they serve as a source of entertainment for the patients, but on the other hand also offer information and communication possibilities. In such systems there can for example also be integrated an emergency call function and a so-called nurse call facility, with which the patient can request help from the care staff if necessary.

The screen of such a system must be able to be positioned ergonomically favourably and reachable by bedridden patients. To this end corresponding screens in the prior art are for example mounted on articulated arms, which are fastened to a wall behind the head end of the bed, as described for example in the document U.S. Pat. No. 3,942,751. It has also been proposed to fix screens directly to the bed frame, to the ceiling, or to a movable column, wherein the column is disposed between the floor and the ceiling.

These proposals are described in the document U.S. Pat. No. 7,911,349 B2. Finally, a movable column with a screen for medical instruments and equipment is known from the document U.S. Pat. No. 5,618,090. This column stands on wheels and is therefore movable. However, it requires a connection to the ceiling in order to be able to connect up supply lines. The unit proposed in this document is not an infotainment system, but instead a type of instrument carrier, which can accommodate numerous medical monitoring and treatment instruments. The column described there accordingly has relatively large dimensions and a column of this size would not be suitable for an infotainment system since it would interfere in routine work in a hospital.

In many hospitals TV programmes and also internet access are offered as an additional facility to the patients, which may involve a charge. In such cases it is advantageous if an infotainment system is provided only for those patients who want this facility. In any case the infotainment system should interfere as little as possible or preferably even simplify normal routine work in the hospital.

An object of the present invention is therefore to provide a generic device in the form of an infotainment system that is flexible to handle and set up, and is as compatible as possible with the demands of a hospital environment.

This object is achieved by a device with the features of claim 1.

Since the device comprises a monitor arm with a touchscreen arranged thereon that can be pulled out from the base body, the device can be set up as a complete infotainment system in the vicinity of the patient's bed. In operation the screen installed on the arm can be pulled out from the housing of the device and arranged in an ergonomically favourable position. After use the screen together with the arm can be retracted into the base body of the device. In this position the device is so compact that it does not interfere for example with treatment and care procedures that are carried out directly at the hospital bed. Also, the device can easily be moved into this position, which facilitates the storage, provision and return of the device to the stored position.

Preferably the arm on which the screen is mounted is a combination of a telescopic column, which as described above can be pulled out from the housing, and a swivel arm that can be swivelled sideways transverse to the axial direction of the telescopic column.

The base body of the device is preferably formed in the shape of a box, with a bottom wall, two long side walls and two short side walls, as well as a cover provided on the upper side. The cover can be formed as a roller-type cover in the manner of a louvre. In the rest position, i.e. when the holding arm and screen are retracted, the cover can completely close the upper side of the base body, so that the holding arm, the telescopic column and the screen are completely enclosed within the base body. Preferably the cover is designed in order that it can be wholly or partly closed also when the holding arm is extended, so that the interior of the base body is not accessible also when the holding arm is extended. In this way it is ensured in particular that the interior of the base body does not become dirty also during use of the device as an infotainment system.

The base body preferably stands on rollers so that the whole device can easily be moved. The underneath of the base body is advantageously wholly or partly open at the bottom, so that cleaning is simplified in that liquid cleaning agents or detergents can be used that can then flow out downwardly from the base body. This is particularly advantageous as regards the ability to disinfect the device. It may furthermore be envisaged that a weight is arranged in the base body in the region of the bottom wall, which acts as a low centre of gravity position of the whole device also when the holding arm is extended. This weight can in practice have roughly the same mass as the holding arm and screen combined.

Alternatively or in addition at least one fastening device in the manner of a bracket or a hook may be provided, with which the device can be detachably fixed to the bed frame. This holding device is preferably arranged on a long side wall, so that the device can be set up parallel to the long side of the hospital bed.

The whole arrangement is preferably designed so that the device is suitable for wet rooms and in particular can be sterilised. A computer can be provided in the interior of the base body, which operates the screen. The computer can however also be arranged in the screen itself. The envisaged electrical connections include a connection for the power supply and a data link, wherein the data connection can be via cables or can be a wireless connection.

One exemplary embodiment of the present invention is described hereinafter with the aid of the drawings, in which:

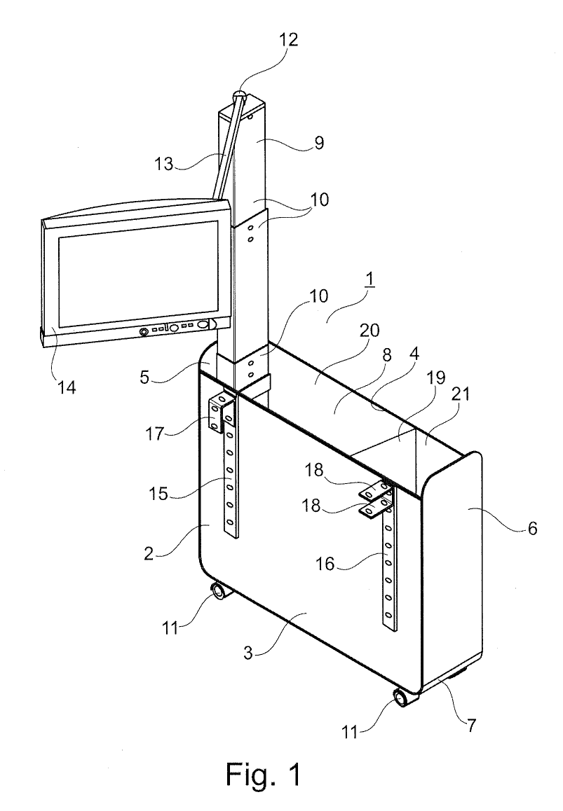

FIG. 1: is a perspective representation of an infotainment system with the screen extended;

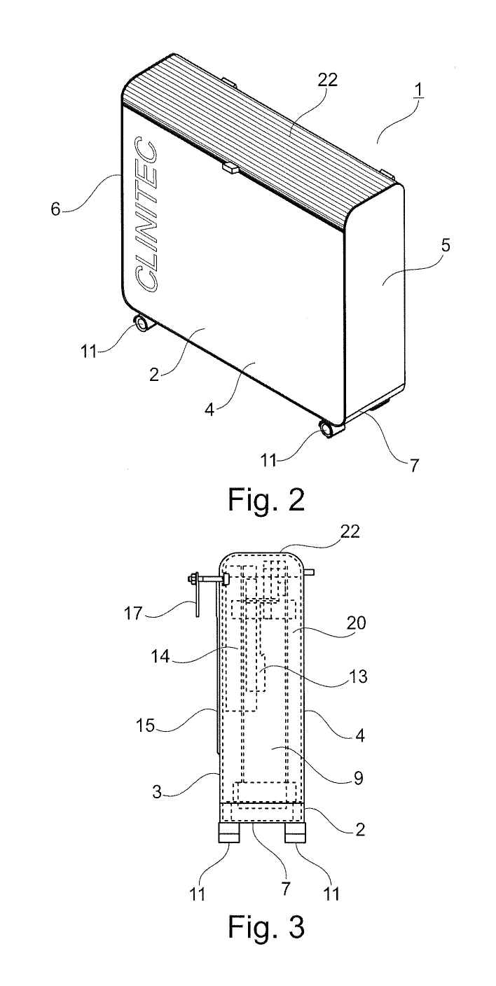

FIG. 2: is a perspective representation of the infotainment system of FIG. 1 with the screen retracted and the cover closed;

FIG. 3: is a front view of the infotainment system of FIG. 2;

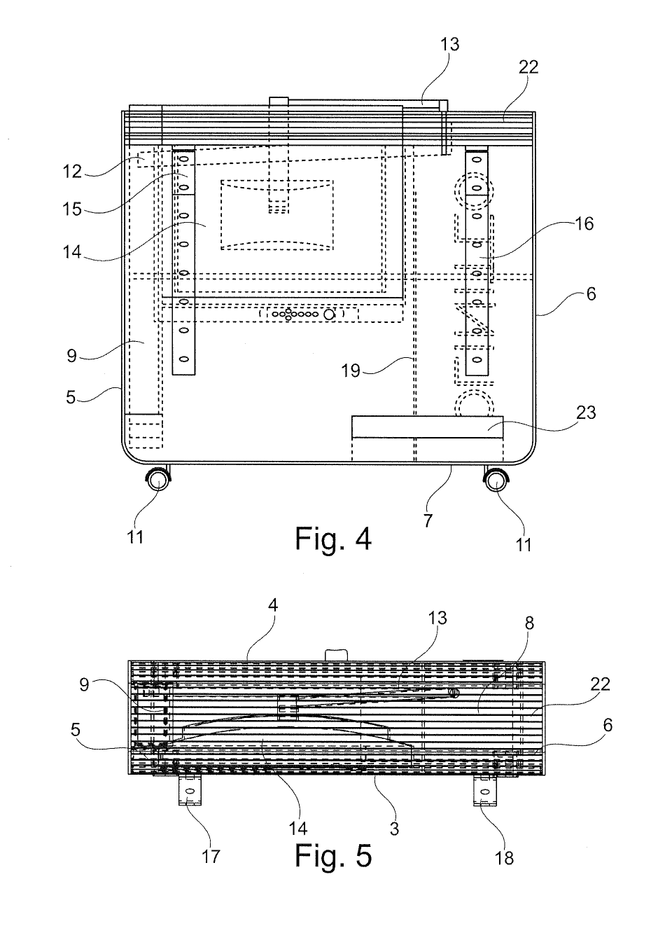

FIG. 4: is a side view of the infotainment system of FIG. 2;

FIG. 5: is a plan view of the infotainment system of FIG. 2;

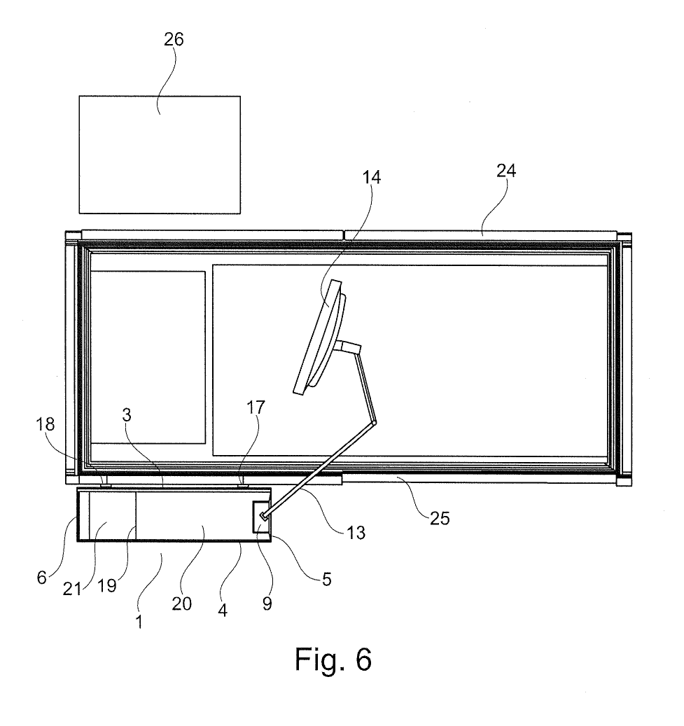

FIG. 6: is a plan view from above of a hospital bed with the infotainment system ready for use;

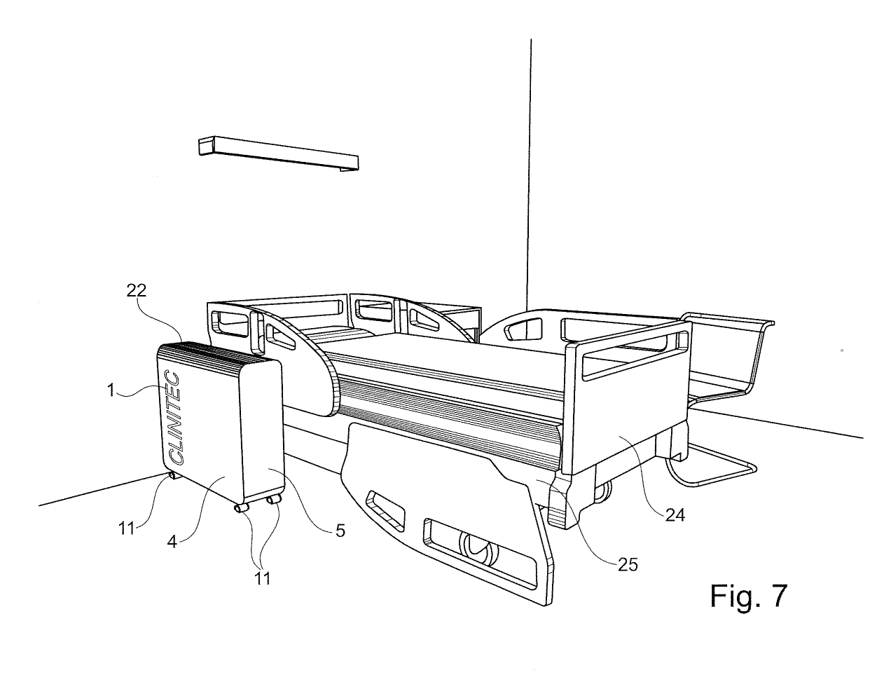

FIG. 7: is a perspective representation of a hospital bed with the provided infotainment system with the monitor retracted and the cover closed; and

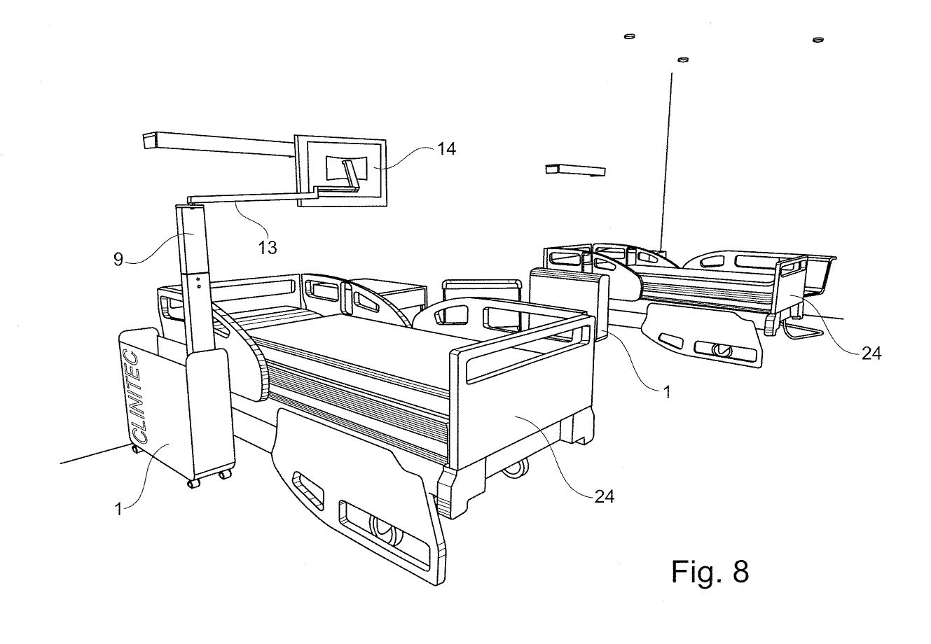

FIG. 8: shows the hospital bed with the infotainment system similar to FIG. 7, but with the screen extended.

FIG. 1 shows a perspective representation of a mobile infotainment system, which is denoted overall by the reference numeral 1. The system comprises a base body 2 with a first long side wall 3, a second long side wall 4, a first short side wall 5 and a second short side wall 6, as well as a bottom wall 7. A cover for closing the base body 2 is provided, but is not shown in FIG. 1.

The base body is formed substantially rectangular and encloses an interior 8. This interior 8 contains various function elements, of which a telescopic column 9 is visible in FIG. 1. The telescopic column is composed of three segments arranged within one another, which are telescopically slidable preferably by means of an electric motor spindle drive (not shown), so that in the retracted state the column 9 is stored completely in the interior 8 of the base body 2. The direction in which the column 9 can be telescoped is in this connection perpendicular to the bottom wall 7. The bottom wall 7 is provided with rollers 11, which stand on the floor of the building when the infotainment system 1 is in use. Accordingly, the bottom wall 7 in use defines a horizontal plane, while the direction in which the telescopic column 9 can be telescoped defines a perpendicular plane. In the interior 8 the telescopic column 9 is aligned parallel to the first short side wall 5 and can for example be fastened directly to the side wall 5.

The column 9 carries on its upper side a swivel joint 12, on which a swivel arm 13 is articulatedly connected. The swivel arm 13 for its part carries a touchscreen 14, via which various functions can be accessed by a user. The screen 14 is designed as a touchscreen so that no separate keyboard is necessary for a complete functionality. This can however be additionally provided.

The first long side wall 3 furthermore carries vertically aligned rails 15 and 16, which are aligned parallel to the side wall 3 and are fastened thereto. The rail 15 has a perforated configuration and includes a hook 17 that is to be arranged in a height-adjustable manner on the perforated configuration, with which the infotainment system 1 can be suspended on a corresponding support, for example on a hospital bed, and thereby prevented from becoming detached. The rail 16 carries an alternative safety device in the form of two U-shaped brackets 18, likewise arranged in a height-adjustable manner on the rail 16. The brackets 18 are formed as horizontally aligned strips enclosing a free space. The brackets 18 form the free arms of a U-shaped profile. A support or a similar compatible component of a hospital bed can be inserted between the brackets 18. On the free end of the brackets 18 there is provided in each case an opening or hole, through which a securement to the hospital bed can be effected with a pin so that the infotainment system 1 is prevented from becoming detached.

The interior 8 finally comprises a subdivision 19, which divides the interior 8 into a larger compartment 20 and a smaller compartment 21. The column 9 is arranged in the larger compartment 20.

FIG. 2 shows the infotainment system 1 of FIG. 1 in a perspective representation. In this representation a cover 22 is provided in the structural form of a roller cover. The cover 22 closes the interior of the base body 2 at the top.

The representation in FIG. 2 shows the infotainment system with the retracted column and the screen retracted in the base body 2, which are therefore not visible in this representation. Also, FIG. 2 shows the base body 2 of FIG. 1 from another side, so that the safety devices 15, 17 and 16, 18 are not visible. The second long side wall 4 is thus visible in FIG. 2.

FIG. 3 shows a cross-sectional front view of the infotainment system of FIGS. 1 and 2. This representation illustrates how the column 9 in the retracted state is accommodated in the compartment 20 and how the screen 14 with its swivel arm 13 is likewise arranged within the compartment 20 of the base body 2. The screen 14 lies substantially with its front side or viewing side on the inside of the first long side wall 3. The cover 22 closes the interior of the base body 2 at the top, as illustrated in FIG. 2. In this way on the one hand an aesthetic appearance of the whole infotainment system 1 when not in use is achieved, and on the other hand the internally accommodated function components and the whole interior are also protected against contamination. The rollers 11 enable the whole infotainment system 1 to be moved easily when the cover 22 is closed, for example to arrange the system around a hospital bed, or after use to remove the system for maintenance, cleaning and storage.

FIG. 4 shows the infotainment system of FIG. 2 in a side view of the first long side wall 3. Identical structural parts are provided with the same reference numerals. In this representation the swivel arm 13 projects upwardly over the partly opened cover 22. This representation shows a weight 23, which is arranged on the underneath of the interior 8 slightly above the bottom wall 7. The weight 23 is disposed in the vicinity of the second short side wall 6, i.e. at a place in the interior 8 that is remote from the column 9. The weight 23 means that when the column is retracted and also when the column 9 is extended, the centre of gravity of the infotainment system 1 is displaced downwardly, preferably below the geometric midpoint of the base body 2 in the direction of the bottom wall 7. The arrangement close to the second short side wall 6 also means that the centre of gravity lies roughly midway between the wheels 11 in FIG. 4. The size and mass of the weight 23 can be adapted to the masses of the column 9 and screen 14. Depending on the desired implementation, steel, concrete or lead are suitable materials for the weight 23.

FIG. 5 shows the infotainment system of FIGS. 2, 3 and 4 in a plan view from above. The cover 22 is closed. The screen 14 with its swivel arm 13 and the column 9, which are not visible when the cover 22 is closed, are illustrated here within the interior 8 in order to show the position of these components in their retracted state within the interior 8 and with the cover closed.

FIG. 6 shows a plan view of the infotainment system 1 in its position in use, namely arranged next to a hospital bed 24. The infotainment system 1 is aligned parallel to the longitudinal side of the hospital bed 24, and specifically so that the first long side wall 3 is aligned parallel to a longitudinal side 25 of the hospital bed 24. The safety devices 17 and 18 respectively are suspended on a profiled section of the longitudinal side 25 of the bed 24, so that the infotainment system 1 is prevented from becoming detached. The column 9 is extended, as has already been illustrated in FIG. 1. The screen 14 has been swivelled with the swivel arm 13 over the hospital bed 24, so that a patient or some other user can view and operate the screen 14. A side table 26 stands on the other side of the hospital bed 24. It can be seen that the dimensions of the infotainment system 1 are relatively small compared to the side table 26, and that the arrangement and use of the infotainment system 1 do not interfere with the functions of the side table 26 if the latter is used for example as a table at mealtimes.

FIG. 7 is a perspective representation of the infotainment system 1, and specifically arranged next to the hospital bed 24 with the cover 22 closed. It can be seen in this representation that the infotainment system has dimensions that do not, or only insignificantly, interfere in the normal working routine in a hospital room. Preferably the infotainment system 1 has a height of 60 to 65 cm, a width (measured in the horizontal direction of the long side wall 4) of 70 to 80 cm and a depth of about 20 cm. Preferred dimensions are a height of 62 cm (measured without the rollers 11), a width of 74 cm and a depth of 20 cm, the depth being measured without the safety devices 17 and 18.

FIG. 8 is a perspective view of a hospital room with two hospital beds 24, wherein the infotainment system 1 in the foreground is illustrated in operational mode with extended column 9 and screen 14 swivelled out, while the rear infotainment system 1 is illustrated in the closed rest position.

1. A mobile information and entertainment unit, including: a base body, which comprises side walls, at least one bottom wall and at least one openable cover, which enclose an interior (8); and a screen for displaying information and entertainment content, wherein the screen is mounted on a swivel arm,
wherein the swivel arm and the screen when in use are disposed outside the interior, wherein the swivel arm and the screen can be stored in a rest position in the interior, and wherein when the screen and swivel arm are stored in the interior the cover can be closed.

2. The information and entertainment unit according to claim 1, further including rollers provided in a region of the bottom wall.

3. The information and entertainment unit according to claim 1, wherein the swivel arm is swivellably fastened to a swivel joint on a telescopic column.

4. The information and entertainment unit according to claim 3, wherein the telescopic column is fastened in the interior to one of the side walls.

5. The information and entertainment unit according to claim 3, wherein the telescopic column is configured to be driven by an electric motor spindle drive.

6. The information and entertainment unit according to claim 1, further including a weight arranged in the interior in the vicinity of the bottom wall and remote from the swivel arm and/or a telescopic column.

7. The information and entertainment unit according to claim 1, wherein the base body comprises openings on its lower side.

8. The information and entertainment unit according to claim 1, wherein the cover is formed as a roller cover.

9. The information and entertainment unit according to claim 1, wherein the cover is configured to be partly or completely closed when the swivel arm is extended.

10. The information and entertainment unit according to claim 1, further including at least one safety device comprising a bracket or a hook wherein the at least one safety device is configured to detachably fasten the base body to a bed frame.

11. The information and entertainment unit according to claim 10, wherein the at least one safety device is arranged on a long side wall of the base body.
